(19) United States
(12) Patent Application Publication
(10) Pub. No.: US 2026/0114009 A1
(43) Pub. Date: Apr. 23, 2026

(54) SEMICONDUCTOR STRUCTURE AND METHOD FOR FORMING A SEMICONDUCTOR STRUCTURE

(71) Applicant: Taiwan Semiconductor Manufacturing Company, Ltd., Hsinchu (TW)

(72) Inventors: Ka-Hing FUNG, Zhudong Township (TW); Huiling SHANG, Hsinchu County (TW); Chi On CHUI, Hsinchu City (TW)

(73) Assignee: Taiwan Semiconductor Manufacturing Company, Ltd., Hsinchu (TW)

(21) Appl. No.: 18/918,935

(22) Filed: Oct. 17, 2024

(51) Int. Cl. H01L 29/66; H01L 29/06; H01L 29/423; H01L 29/775; H01L 29/786

(52) U.S. Cl. CPC H10D 64/018; H10D 30/014; H10D 30/43; H10D 30/6735; H10D 30/6757; H10D 62/121; H10D 64/017; H10D 64/021; H10D 30/6736

(57) ABSTRACT

A method for forming a semiconductor structure includes alternately forming a plurality of channel layers and a plurality of sacrificial layers over a substrate. The method also includes forming a source/drain trench through the channel layers and the sacrificial layers. The method also includes replacing the sacrificial layers with a plurality of dummy oxide layers. Sidewalls of the dummy oxide layers are substantially aligned with sidewalls of the channel layers. The method also includes selectively forming a plurality of inner spacers on the sidewalls of the dummy oxide layers through the source/drain trench. The method also includes replacing the dummy oxide layers with a gate structure.

### BACKGROUND

Semiconductor devices are widely used in various electronic applications, such as personal computers, mobile phones, digital cameras, and other electronic equipment. As the size of semiconductor devices shrinks, the difficulty of manufacturing semiconductor devices has also increased significantly. Defects may occur during the process of manufacturing semiconductor devices, and these defects may cause failure, or they may cause the performance of the semiconductor devices to suffer. Therefore, further improvements in semiconductor devices are required.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A to 1D illustrate perspective views of various stages of manufacturing a semiconductor structure in accordance with some embodiments of the present disclosure.

FIGS. 2A to 2I illustrate cross-sectional views of various stages of manufacturing a semiconductor structure in accordance with some embodiments of the present disclosure.

FIG. 3 illustrates a cross-sectional view of a semiconductor structure in accordance with some embodiments of the present disclosure.

FIG. 4 illustrates a cross-sectional view of a semiconductor structure in accordance with some embodiments of the present disclosure.

FIGS. 5A to 5H illustrate cross-sectional views of various stages of manufacturing a semiconductor structure in accordance with some embodiments of the present disclosure.

FIG. 6 illustrates a cross-sectional view of a semiconductor structure in accordance with some embodiments of the present disclosure.

FIG. 7 illustrates a cross-sectional view of a semiconductor structure in accordance with some embodiments of the present disclosure.

FIG. 8 illustrates a cross-sectional view of a semiconductor structure in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The nanostructure transistor (e.g. nanosheet transistor, nanowire transistor, multi-bridge channel, nano-ribbon FET, gate all around (GAA) transistor structures described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Semiconductor structures and methods for forming a semiconductor structure are described in accordance with some embodiments of the present disclosure. The semiconductor structure may be a gate-all-around (GAA) transistor structure. The method may include selectively forming a plurality of nitride spacers on oxide layers. In comparison with forming inner spacers by multiple etching and deposition, manufacturing processes can be simplified. As a result, the product level speed and standby power variation can be improved.

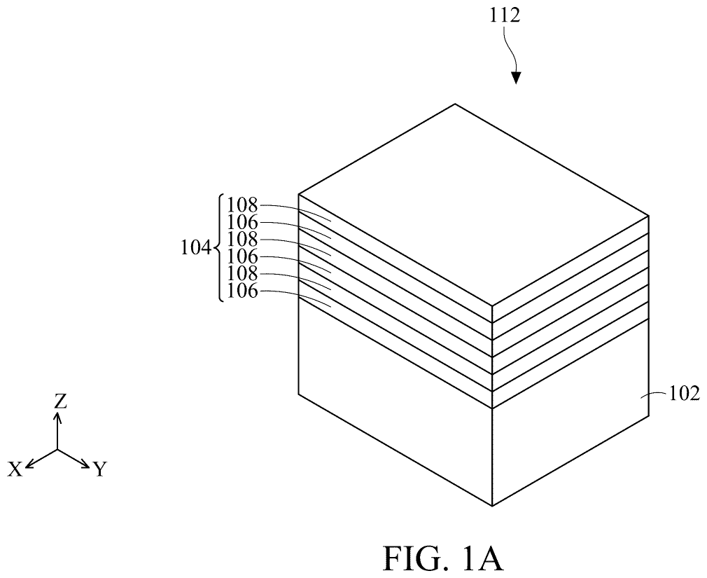

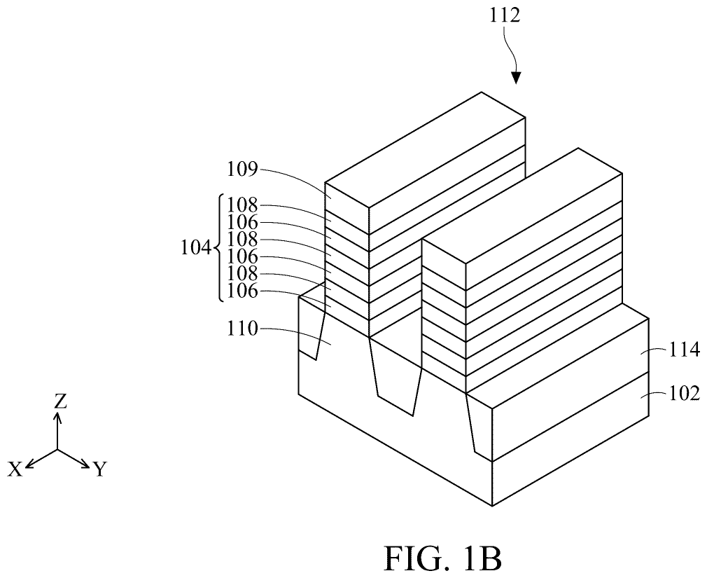

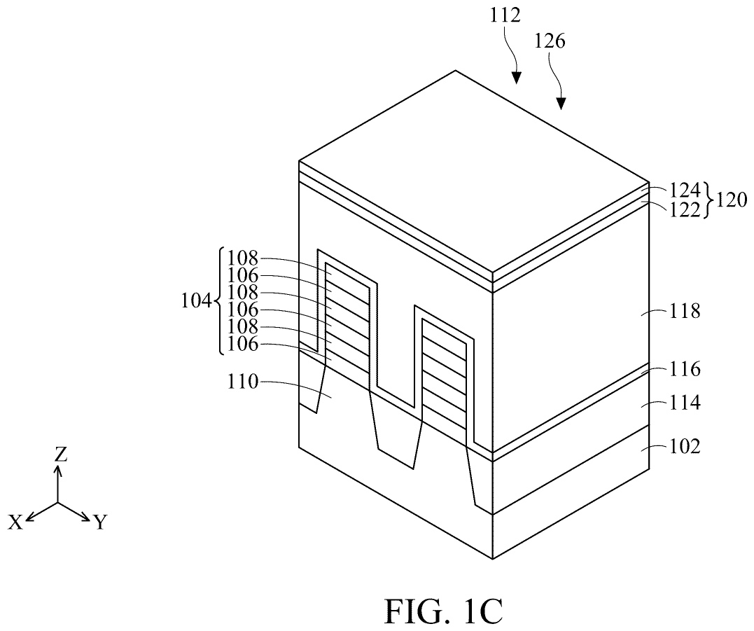

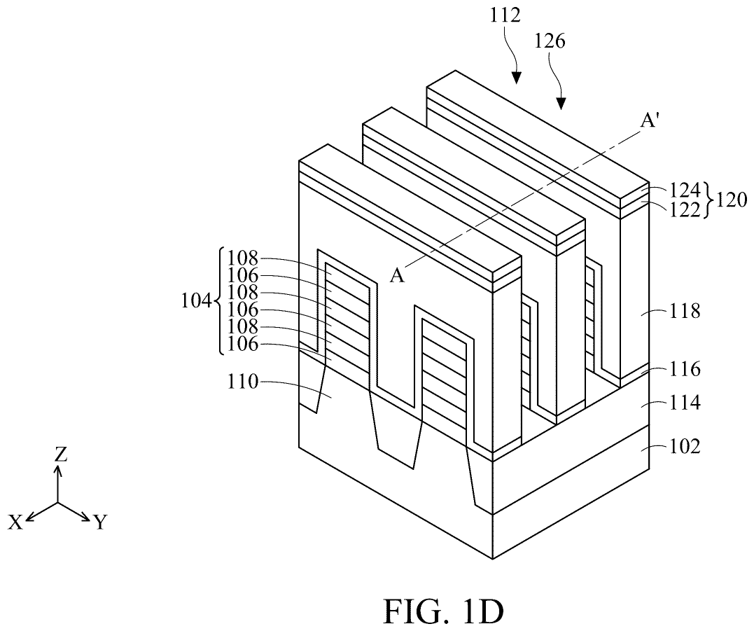

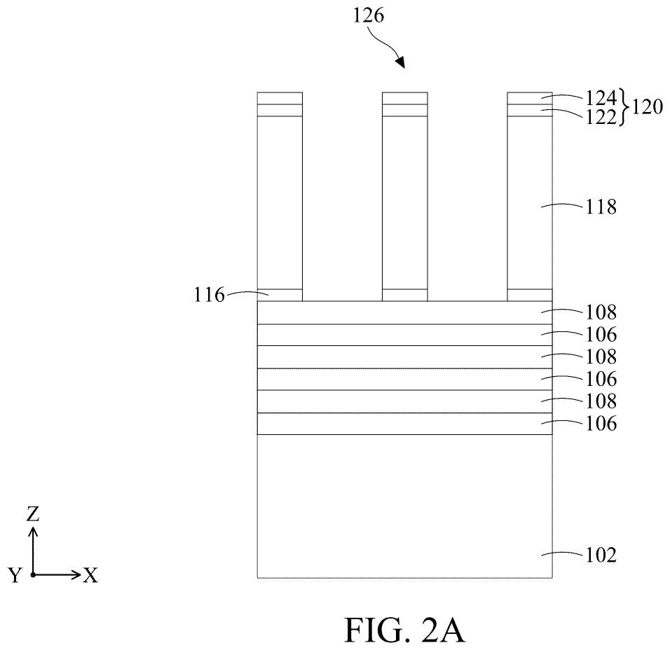

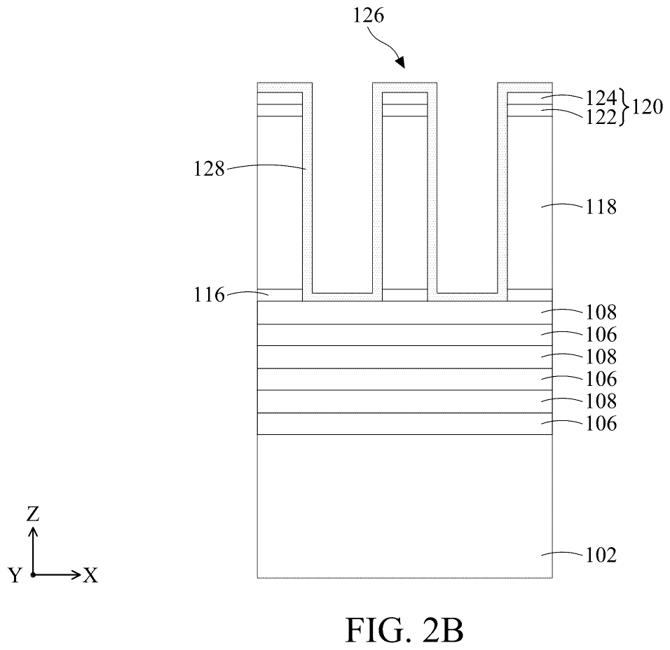

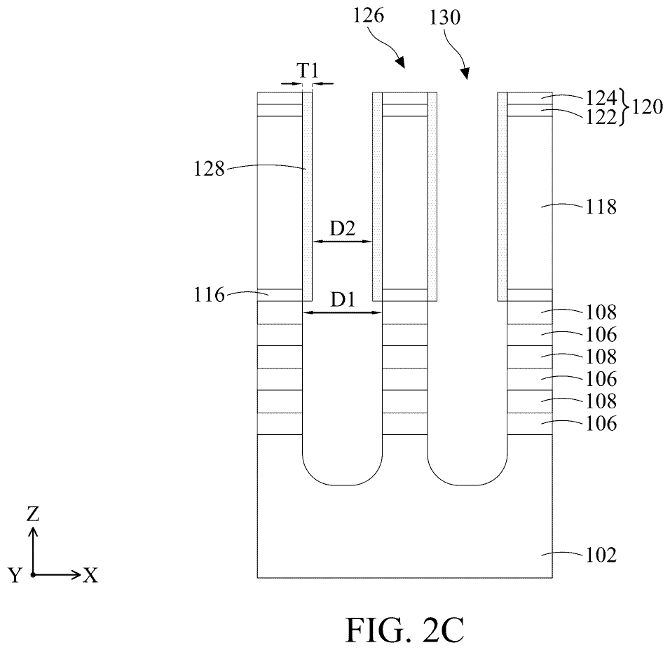

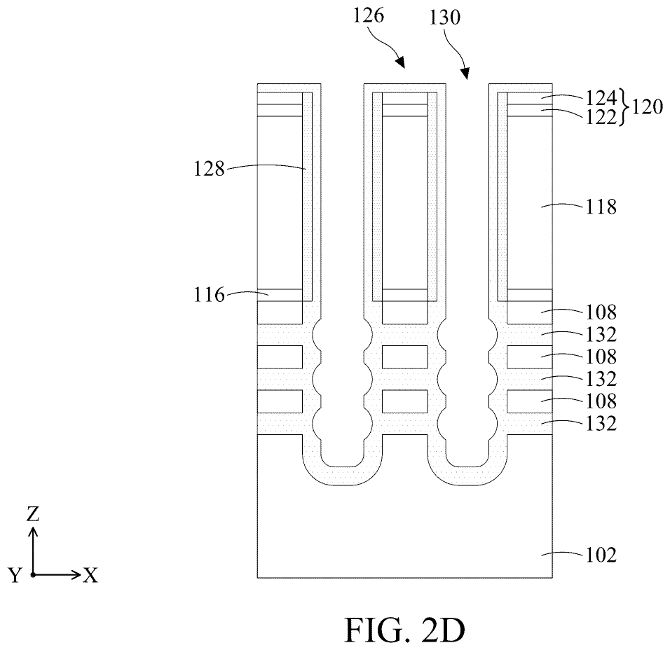

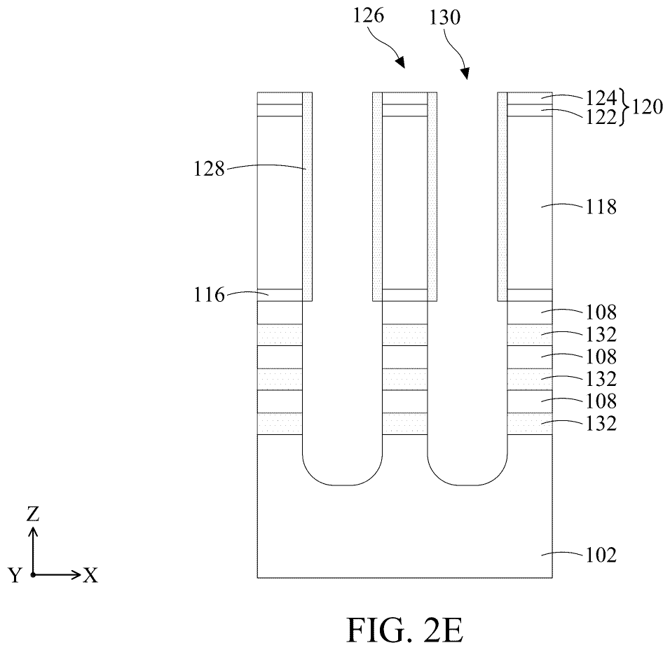

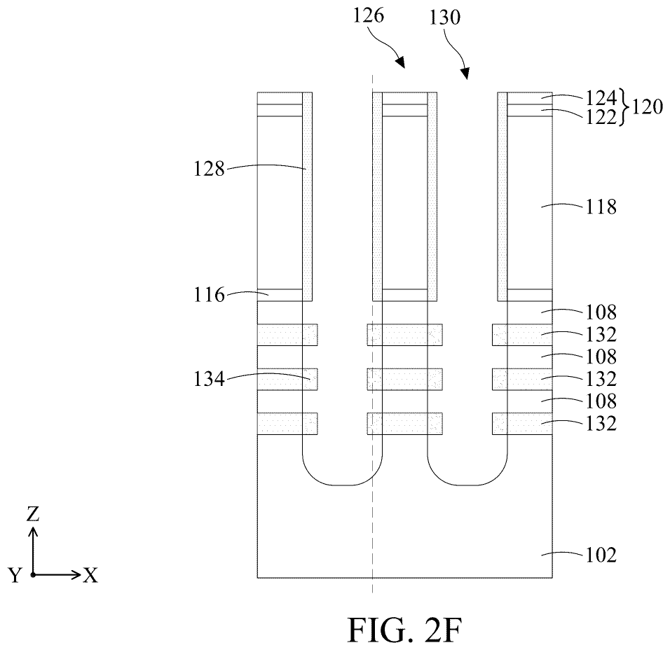

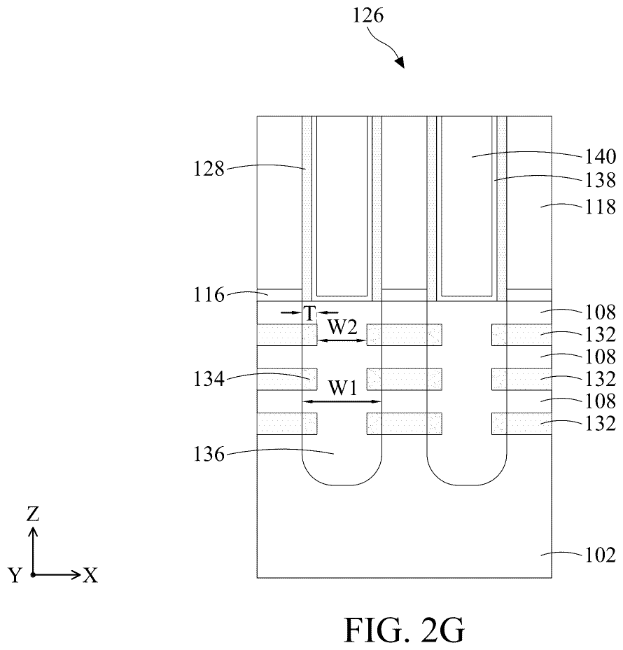

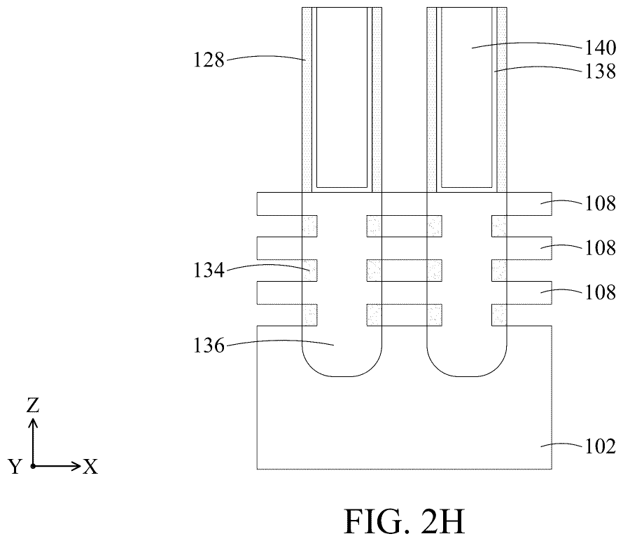

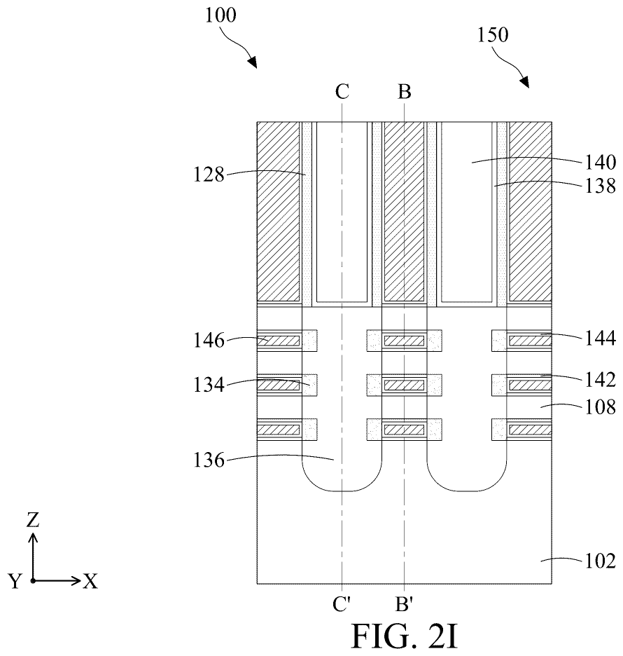

FIGS. 1A to 1D illustrate perspective views of various stages of manufacturing a semiconductor structure 100 in accordance with some embodiments of the present disclosure. FIGS. 2A to 2I illustrate cross-sectional views of various stages of manufacturing the semiconductor structure 100 in accordance with some embodiments of the present disclosure. FIGS. 2A to 2I illustrate cross-sectional views taken along line A-A′ shown in FIG. 1D. Additional features can be added to the semiconductor structure 100. Some of the features described below can be replaced or eliminated for different embodiments. To simplify the diagram, only a portion of the semiconductor structure 100 is illustrated.

As illustrated in FIG. 1A, a stack 104 is formed over a substrate 102, in accordance with some embodiments. The substrate 102 may be a semiconductor wafer, such as a silicon wafer. The substrate 102 may be formed of elementary semiconductor materials, compound semiconductor materials, alloy semiconductor materials, the like, or a combination thereof. Examples of the elementary semiconductor materials may include crystal silicon, polycrystalline silicon, amorphous silicon, germanium, diamond, the like, or a combination thereof. Examples of the compound semiconductor materials may include silicon carbide, gallium nitride, gallium arsenic, gallium phosphide, indium phosphide, indium arsenide, indium antimonide, the like, or a combination thereof. Examples of the alloy semiconductor materials may include SiGe, GaAsP, AlInAs, AlGaAs, GaInAs, GaInP, GaInAsP, the like, or a combination thereof. Alternatively, the substrate 102 may be semiconductor on insulator, including a silicon-on-insulator (SOI), a germanium-on-insulator (GeOI), the like, or a combination thereof.

The substrate 102 may be doped with P-type or N-type dopants. For example, the P-type dopants may include boron (B), boron difluoride (BF₂), gallium (Ga), or a combination thereof, and the N-type dopants may include phosphorus (P), arsenic (As), antimony (Sb), or a combination thereof.

The stack 104 may include a plurality of channel layers 108 interleaved by a plurality of sacrificial layers 106. The sacrificial layers 106 and the channel layers 108 may be made of different materials with different etching rates. For example, the sacrificial layers 106 may be formed of silicon germanium (SiGe) or germanium tin (GeSn), and the channel layers 108 may be formed of silicon. The sacrificial layers 106 and the channel layers 108 may each be independently formed by using low-pressure chemical vapor deposition (LPCVD), ultra-high vacuum CVD (UHV-CVD), molecular beam epitaxy (MBE), metal organic chemical vapor deposition (MOCVD), vapor phase epitaxy (VPE), the like, or a combination thereof.

It should be noted that three layers of the sacrificial layers 106 and three layers of the channel layers 108 as shown in FIG. 1A are for illustrative purposes only, and more or less numbers of layers may be alternately formed. The number of layers may depend on the desired number of channels members for the semiconductor structure 100, such as 2 to 10.

Then, as illustrated in FIG. 1B, a patterned mask layer 109 is formed over the stack 104, in accordance with some embodiments. The stack 104 may be patterned to form fin structures 112 using a photolithography process and an etch process with the patterned mask layer 109. Each of the fin structures 112 may include a base portion 110 and the semiconductor material stack of the sacrificial layers 106 and the channel layers 108 thereon.

The patterned mask layer 109 may be a single layer or a multi-layer structure. For example, the patterned mask layer 109 may include an oxide layer and a nitride layer over the pad oxide layer. The oxide layer may be made of silicon oxide, which may be formed by using a thermal oxidation process, a chemical vapor deposition (CVD) process or another suitable process. The nitride layer may be made of silicon nitride, which may be formed by using a CVD process, including LPCVD, plasma-enhanced CVD (PECVD), another suitable process, or a combination thereof.

The photolithography process may include photoresist coating (e.g., spin-on coating), soft baking, mask aligning, exposure, post-exposure baking, photoresist developing, rinsing, drying (e.g., spin-drying and/or hard baking), another suitable photolithography techniques, or a combination thereof. The etching process may include a dry etching (e.g., reactive ion etching (RIE)) process, a wet etching process, or a combination thereof. It should be noted that two fin structures 112 are for illustrative purposes only, and the number of the fin structures 112 is not limited to two.

Then, an isolation structure 114 is formed in the trenches between the fin structures 112 to electrically isolate adjacent fin structures 112, in accordance with some embodiments. The isolation structure 114 may be a shallow trench isolation (STI) structure. The isolation structure 114 may be formed by filling an insulating material, including silicon oxide, silicon nitride, silicon oxynitride (SiON), SiOCN, SiCN, fluoride-doped silicate glass (FSG), other low-k dielectric materials, or a combination thereof. The insulating material may be formed by a deposition process, including a CVD (such as flowable CVD (FCVD), PECVD, or LPCVD) process, a spin-on-glass process, another suitable process, or a combination thereof.

A planarization process, including a grinding process, a chemical mechanical polishing (CMP) process, an etching process, another suitable process, or a combination thereof, may be performed to remove the patterned mask layer 109 and to expose the top portions of the fin structures 112. Then, the insulating material may be etched back by an etching process to form the isolation structure 114 and to expose the stack 104. The etching process may include a dry etching process, a wet etching process, or a combination thereof.

The isolation structure 114 may be a multi-layer structure, for example, having one or more liner layers. The liner layer may be formed in the trenches before filling the insulating material. The liner layer may be formed of silicon nitride or another suitable material and may be formed by using a thermal oxidation process, a CVD process (e.g., a FCVD process, a PECVD process, or a LPCVD process), an atomic layer deposition (ALD) process (e.g., a plasma enhanced ALD (PEALD) process), another suitable process, or a combination thereof.

Then, as illustrated in FIG. 1C, dummy gate structures 126 are formed across the fin structure 112 and over the isolation structure 114, in accordance with some embodiments. The dummy gate structures 126 may each include a dummy gate dielectric layer 116 and a dummy gate electrode layer 118 over the dummy gate dielectric layer 116. The dummy gate dielectric layer 116 and the dummy gate electrode layer 118 may be replaced by the following steps to form a real gate structure with a high-k dielectric layer and a metal gate electrode layer.

The dummy gate dielectric layer 116 may be conformally formed over the fin structure 112 to have substantially uniform thickness over various regions. The dummy gate dielectric layer 116 may be made of dielectric materials, including silicon oxide, silicon nitride, silicon oxynitride (SiON), HfO₂, HfZrO, HfSiO, HfTiO, HfAlO, another suitable dielectric material, or a combination thereof. Alternatively, the dummy gate dielectric layer 116 may be made of a high-k dielectric layer (e.g., the dielectric constant is greater than 3.9), including hafnium oxide (HfO₂), LaO, AlO, ZrO, TiO, Ta₂O₅, Y₂O₃, SrTiO₃, BaTiO₃, BaZrO, HfZrO, HfLaO, HfTaO, HfSiO, HfSiON, HfTiO, LaSiO, AlSiO, (Ba, Sr)TiO₃, Al₂O₃, another suitable high-k dielectric material, or a combination thereof. The dummy gate dielectric layer 116 may be formed using an oxidation process (e.g., a dry oxidation process or a wet oxidation process), a CVD process, an ALD process, a physical vapor deposition (PVD) process (e.g., a vacuum evaporation process or a sputtering process), another suitable method, or a combination thereof.

The dummy gate electrode layer 118 may be made of conductive materials, including polycrystalline-silicon (poly-Si), poly-crystalline silicon-germanium (poly-SiGe), metallic nitrides, metallic silicides, metals, another suitable conductive material, or a combination thereof. The dummy gate electrode layer 118 may be formed using CVD, PVD, another suitable method, or a combination thereof.

Then, a gate-top hard mask layer 120 is formed over the dummy gate structures 126, in accordance with some embodiments. The gate-top hard mask layer 120 may include an oxide layer 122 and a nitride layer 124 over the oxide layer 122. The oxide layer 122 may be made of silicon oxide, which may be formed by a thermal oxidation process, a CVD process, or another suitable process. The nitride layer 124 may be made of silicon nitride, which may be formed by using a CVD process, including LPCVD, PECVD, or another suitable process.

The material of dummy gate dielectric layer 116 and the material of dummy gate electrode layer 118 may be patterned to form the dummy gate structures 126 using a photolithography process and an etch process with the gate-top hard mask layer 120, in accordance with some embodiments. The etching process may include a dry etching (e.g., RIE) process, a wet etching process, or a combination thereof. After the patterning, the dummy gate structure 126 may be formed over channel regions, as illustrated in FIGS. 1D and 2A.

Then, as illustrated in FIG. 2B, a spacer layer 128 is conformally formed over the stack 104 and the dummy gate structure 126, in accordance with some embodiments. The spacer layer 128 may be made of dielectric materials, including silicon oxide, silicon nitride, silicon oxynitride, silicon carbonitride, silicon oxycarbide, silicon oxycarbonitride, another suitable material, or a combination thereof. The spacer layer 128 may be formed by a deposition process, including a CVD (such as FCVD, PECVD, or LPCVD) process, a spin-on-glass process, another suitable process, or a combination thereof.

Then, as illustrated in FIG. 2C, the spacer layer 128 is etched by an etching process to form a pair of spacer layers 128 on opposite sidewalls of each of the dummy gate structures 126, in accordance with some embodiments. The etching process may include a dry etching (e.g., RIE) process, a wet etching process, or a combination thereof. In some embodiments, the sacrificial layers 106 and the channel layers 108 are partially removed in the etching process using the spacer layers 128 as the mask to form an opening, and then the opening is widen by a trimming process to form a source/drain trench 130. The source/drain trench 130 may extend vertically through the depth of the stack 104 and may partially extend into the substrate 102.

The trimming process may laterally remove the outer portions of the sacrificial layers 106 and the channel layers 108, so that the widths of the channel layers 108 and the gate wrapping around the channel layers 108 formed in subsequent processes can be shortened. Therefore, the capacitance of the resulting device may be reduced. The trimming process may include a dry etching process or another suitable process. After the trimming process, the bottom surfaces of the spacer layers 128 may be exposed by the source/drain trench 130. In particular, the sidewall of the source/drain trench 130 may be substantially aligned with the sidewall of the dummy gate structure 126.

In some embodiments, the distance D1 between the stacks 104 (i.e., the width of the source/drain trench 130) is greater than the distance D2 between the spacer layers 128 on adjacent dummy gate structures 126. The distance D1 between the stacks 104 may be substantially equal to the sum of the distance D2 between the spacer layers 128 and the thickness T1 of the spacer layers 128 on adjacent dummy gate structures 126. The thickness T1 of the spacer layers 128 may be in a range of about 5 to about 6 nm.

Then, as illustrated in FIG. 2D, the sacrificial layers 106 are removed to form a plurality of gate openings between the channel layers 108, in accordance with some embodiments. The channel layers 108 may be released. The removal process may include a selective etching process, which may remove the sacrificial layers 106 and remain the channel layers 108 as nanostructures 108. The nanostructures 108 may include nanowires, nanorods, nanosheets, or another suitable nanostructures. The selective etching process may include a selective wet etching process, a selective dry etching process, or a combination thereof. For example, the selective etching process may be a plasma-free dry chemical etching process. The etchant of the dry chemical etching process may include radicals, including HF, NF₃, NH₃, H₂, another suitable etchant, or a combination thereof.

Next, a dummy oxide layer 132 is formed in the gate openings and conformally on the sidewalls of the source/drain trench 130, in accordance with some embodiments. The dummy oxide layer 132 may be made of oxide, such as silicon oxide. The dummy oxide layer 132 may include a multi-layer structure, for example, silicon oxide with different quality, density, or the like. The dummy oxide layer 132 may be deposited using a CVD process (e.g., a FCVD process, a PECVD process, or a LPCVD process), an ALD process, another suitable process, or a combination thereof. For example, the dummy oxide layer 132 may include a thin film formed by a PECVD process and a bulk material formed by a FCVD process.

Then, as illustrated in FIG. 2E, the dummy oxide layer 132 is partially etched to remove the portions of the dummy oxide layer 132 outside the channel layers 108, in accordance with some embodiments. The dummy oxide layer 132 may be partially etched by a selective etching process, including a selective wet etch process, a selective dry etch process, or a combination thereof. Examples of the selective wet etch process may include using etchants including diluted hydrofluoric acid (DHF), a mixture of hydrofluoric acid (HF) and ammonium fluoride (NH₄F), another suitable etchants, or a combination thereof. Examples of the selective dry etch process may include using etchants including anhydrous hydrogen fluoride (HF) vapor, trifluoromethane (CHF₃), nitrogen trifluoride (NF₃), hydrogen (H₂), ammonia (NH₃), carbon tetrafluoride (CF₄), sulfur hexafluoride (SF₆), another suitable etchants, or a combination thereof.

Then, as illustrated in FIG. 2F, a plurality of nitride spacers 134 are selectively formed on sidewalls of the dummy oxide layer 132 through the source/drain trench 130, in accordance with some embodiments. The nitride spacers 134 may also be referred to as inner spacers or nitride inner spacers. The nitride spacers 134 may be formed by a deposition process, including a CVD process (such as LPCVD, PECVD, SACVD, or FCVD), an ALD process, another suitable process, or a combination thereof. The nitride spacers 134 may be made of nitride, including silicon nitride, silicon carbon nitride (SiCN), silicon oxide carbonitride (SiOCN), another suitable material, or a combination thereof.

The nitride spacers 134 may be selectively deposited on the surfaces of an oxide, i.e., the surfaces of the dummy oxide layer 132, but not on the surfaces of the channel layers 108. By selectively forming the nitride spacers 134 on the dummy oxide layer 132, multiple etching and deposition for forming inner spacers can be omitted, thereby simplifying the manufacturing processes. Therefore, the product level speed and standby power variation can be improved.

The nitride inner spacers 134 may laterally extend (such as laterally protrude) from the sidewall of the dummy oxide layer 132. The inner sidewalls of the nitride inner spacers 134 may be substantially aligned with the sidewalls of the dummy oxide layer 132 and substantially aligned with the sidewalls of the channel layers 108. The nitride inner spacers 134 may laterally extend (such as laterally protrude) from the sidewall of the spacer layers 128 when viewed from above, or from a direction that is parallel to the sidewall of the spacer layers 128, as indicated by the dashed line in FIG. 2F.

In some embodiments where the isolation structure 114 (as illustrated in FIG. 1D) includes oxide, a nitride layer may also be formed on the isolation structure 114 during the formation of the nitride spacers 134 to improve isolation.

Then, as illustrated in FIG. 2G, a source/drain structure 136 is formed in the source/drain trench 130, in accordance with some embodiments. The source/drain structure(s) may refer to a source or a drain, individually or collectively dependent upon the context. The source/drain structure 136 may be formed by growing strained materials in the source/drain trench 130 by an epitaxial process. The lattice constant of the strained material may be different from the lattice constant of the substrate 102. The source/drain structure 136 may be made of Ge, SiGe, InAs, InGaAs, InSb, GaAs, GaSb, InAlP, InP, SiC, SiP, another suitable material, or a combination thereof. The source/drain structure 136 may be formed by an epitaxial growth process, including a MOCVD process, a metalorganic vapor phase epitaxy (MOVPE) process, a PECVD process, a remote plasma-enhanced chemical vapor deposition (RP-CVD) process, a molecular beam epitaxy (MBE) process, a hydride vapor phase epitaxy (HVPE) process, a liquid phase epitaxy (LPE) process, a chloride vapor phase epitaxy (Cl-VPE) process, another suitable process, or a combination thereof.

The source/drain structure 136 may be doped with one or more dopants. The source/drain structure 136 may be doped with in-situ doping, which may include adding dopants to a source material of the epitaxy process during the deposition. In the embodiments where the source/drain structure 136 is n-type, the source/drain structure 136 includes silicon (Si) and an n-type dopant, such as phosphorus (P), arsenic (As), antimony (Sb), or a combination thereof. In the embodiments where the source/drain structure 136 is p-type, the source/drain structure 136 includes silicon germanium (SiGe) and a p-type dopant, such as boron (B), boron difluoride (BF₂), gallium (Ga), or a combination thereof.

The outermost sidewall of the source/drain structure 136 may be substantially aligned with the sidewall of the spacer layers 128. The source/drain structure 136 may extend from a sidewall of the nitride inner spacers 134 to another sidewall of the nitride inner spacers 134 and may encapsulate the nitride inner spacers 134. The outermost sidewall of the source/drain structure 136 may be substantially aligned with the interface between the nitride inner spacers 134 and the dummy oxide layer 132.

In some embodiments, portions of the source/drain structure 136 are vertically sandwiched between the nitride inner spacers 134, between the top most one of the nitride inner spacers 134 and the spacer layer 128, and between the bottommost one of the nitride inner spacers 134 and the substrate 102. In some embodiments, the source/drain structure 136 has a first width W1 between the channel layers 108 and a second width W2 between the nitride inner spacers 134. The first width W1 may be greater than the second width W2. The first width W1 may be substantially equal to the sum of the second width W2 and the thicknesses T of two nitride inner spacers 134 on opposite surfaces of the source/drain structure 136.

Then, an etch stop layer 138 is formed over the source/drain structure 136, in accordance with some embodiments. The etch stop layer 138 may be made of silicon nitride, silicon oxide, silicon oxynitride (SiON), another suitable materials, or a combination thereof. The etch stop layer 138 may be formed using a CVD process (e.g., a PECVD process, or a MOCVD process), an ALD process (e.g., a PEALD process), a PVD process (e.g., a vacuum evaporation process, or a sputtering process), another suitable processes, or a combination thereof.

Then, an inter-layer dielectric (ILD) structure 140 is formed over the etch stop layer 138, in accordance with some embodiments. The ILD structure 140 may be a multi-layer structure made of multiple dielectric materials, including silicon oxide, silicon oxycarbide, silicon oxycarbonitride, silicon nitride, silicon oxynitride, tetraethyl orthosilicate (TEOS) oxide, phosphosilicate glass (PSG), borophosphosilicate glass (BPSG), low-k dielectric materials, another suitable dielectric material, or a combination thereof. Examples of low-k dielectric materials may include fluorinated silica glass (FSG), carbon doped silicon oxide, amorphous fluorinated carbon, parylene, bis-benzocyclobutenes (BCB), polyimide, another suitable materials, or a combination thereof. The ILD structure 140 may be formed using a CVD (such as flowable CVD (FCVD), PECVD, or LPCVD) process, a spin-on coating process, another suitable processes, or a combination thereof.

Then, a planarization process is performed on the ILD structure 140 until the top surface of the dummy gate structure 118 is exposed, in accordance with some embodiments. The planarization process may include a grinding process, a chemical mechanical polishing (CMP) process, an etching process, another suitable process, or a combination thereof. After the planarization process, the top surface of the dummy gate structure 118 may be substantially level with the top surfaces of the spacer layers 128, the etch stop layer 138, and the ILD structure 140.

Then, as illustrated in FIG. 2H, the dummy gate structure 118 is removed using an etching process, in accordance with some embodiments. The etching process may include a dry etching process, a wet etching process, or a combination thereof. Afterwards, the dummy oxide layer 132 may be selectively etched to expose the channel layers 108. The selective etching process may include a selective wet etching process, a selective dry etching process, or a combination thereof. Examples of the selective wet etch process may include using etchants including diluted hydrofluoric acid (DHF), a mixture of hydrofluoric acid (HF) and ammonium fluoride (NH₄F), another suitable etchants, or a combination thereof. Examples of the selective dry etch process may include using etchants including anhydrous hydrogen fluoride (HF) vapor, trifluoromethane (CHF₃), nitrogen trifluoride (NF₃), hydrogen (H₂), ammonia (NH₃), carbon tetrafluoride (CF₄), sulfur hexafluoride (SF₆), another suitable etchants, or a combination thereof.

Then, as illustrated in FIG. 2I, gate structures 150 are formed surrounding the channel layers 108, in accordance with some embodiments. Each of the gate structures 150 may include an interfacial layer 142, a high-k dielectric layer 144, and a gate electrode layer 146. The channel layers 108 may be surrounded and in direct contact with the interfacial layer 142. The high-k dielectric layer 144 may be surrounded by the interfacial layer 142. The high-k dielectric layer 144 may be surrounded by the gate electrode layer 146.

The interfacial layer 142 may be made of silicon oxide, and may be formed by using a thermal oxidation process. The high-k dielectric layer 144 may be made of dielectric material, including HfO₂, HfSiO, HfSiON, HfTaO, HfTiO, HfZrO, zirconium oxide, aluminum oxide, titanium oxide, hafnium dioxide-alumina (HfO₂-Al₂O₃) alloy, another suitable high-k dielectric material, or a combination thereof. The high-k dielectric layer 144 may be formed by using a CVD process (e.g., a FCVD process, a PECVD process, or a LPCVD process), an ALD process, another suitable method, or a combination thereof.

The gate electrode layer 146 may include one or more work function layers and a metal fill layer. The work function layers may be made of metal materials. In some embodiments, the metal materials are P-work-function metals, including titanium nitride (TiN), tungsten nitride (WN), tantalum nitride (TaN), ruthenium (Ru), another suitable material, or a combination thereof. In some embodiments, the metal materials are N-work-function metals, including tungsten (W), copper (Cu), titanium (Ti), silver (Ag), aluminum (Al), titanium aluminum alloy (TiAl), titanium aluminum nitride (TiAlN), tantalum carbide (TaC), tantalum carbon nitride (TaCN), tantalum silicon nitride (TaSiN), manganese (Mn), zirconium (Zr), another suitable material, or a combination thereof. The work function layers may be formed by using a CVD process (e.g., a FCVD process, a PECVD process, or a LPCVD process), an ALD process, another suitable method, or a combination thereof.

The metal fill layer may be made of one or more conductive materials, including polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, another suitable material, or a combination thereof. The metal fill layer may be formed by using a CVD process (e.g., a FCVD process, a PECVD process, or a LPCVD process), an ALD process, electroplating, another suitable method, or a combination thereof.

Then, a planarization process is performed until the ILD structure 140 is exposed, in accordance with some embodiments. The planarization process may include a grinding process, a CMP process, an etching process, another suitable process, or a combination thereof. The semiconductor structure 100 may be formed.

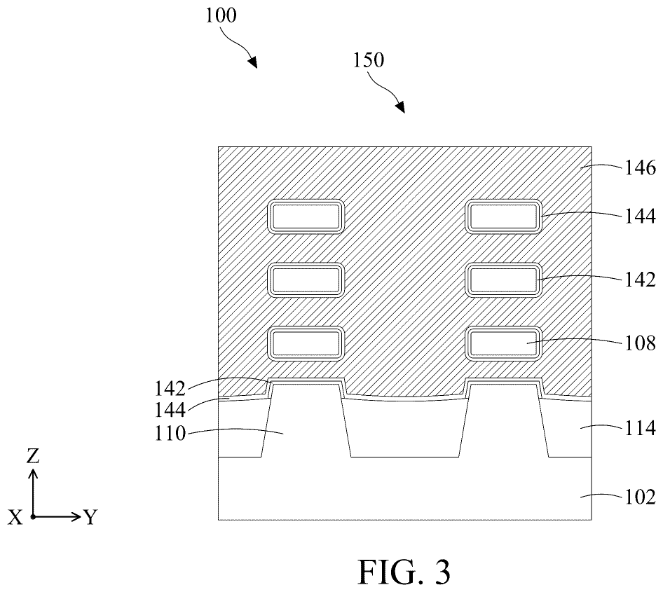

FIG. 3 illustrates a cross-sectional view of the semiconductor structure 100 shown along line B-B′ in FIG. 2I in accordance with some embodiments of the present disclosure.

As illustrated in FIG. 3, the isolation structure 114 may be formed between the base portions 110. The channel layers 108 may be stacked over the base portions 110 and may each be wrapped around by the interfacial layer 142. The interfacial layer 142 may be wrapped around by the high-k dielectric layer 144. The gate electrode layer 146 may be formed to cover the isolation structure 114, the base portions 110, and may wrap around the high-k dielectric layer 144. The gate electrode layer 146 may wrap around the channel layers 108 and may fill the gaps between the channel layers 108 form a GAA transistor structure.

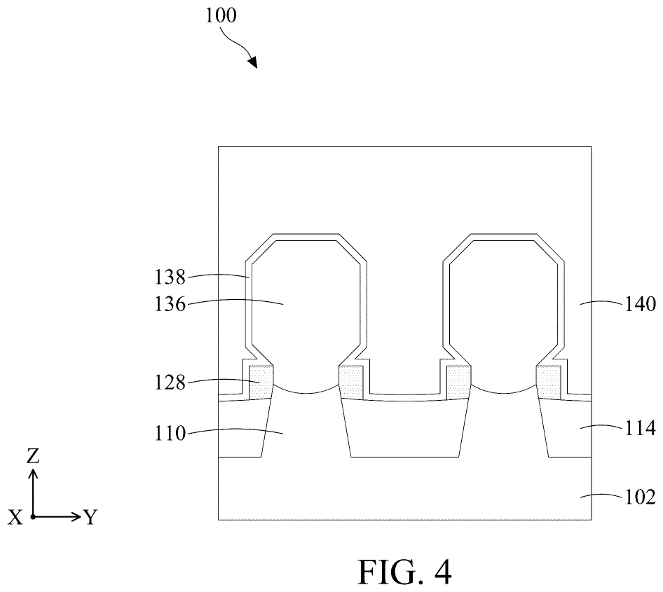

FIG. 4 illustrates a cross-sectional view of the semiconductor structure 100 shown along line C-C′ in FIG. 2I in accordance with some embodiments of the present disclosure.

As illustrated in FIG. 4, the spacer layers 128 may be formed over the isolation structure 114 and on opposite sides of the source/drain structure 136. The etch stop layer 138 may be formed over the isolation structure 114 and cover the source/drain structure 136 and the spacer layers 128. The ILD structure 140 may be formed to cover the etch stop layer 138.

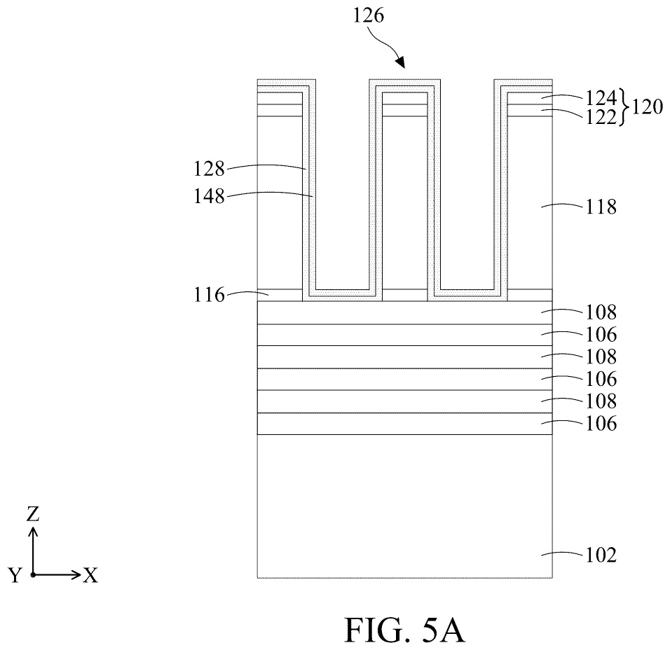

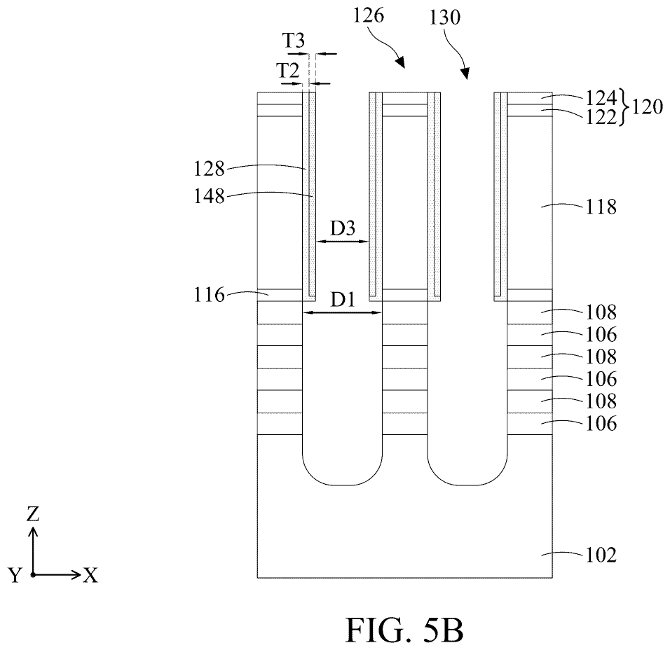

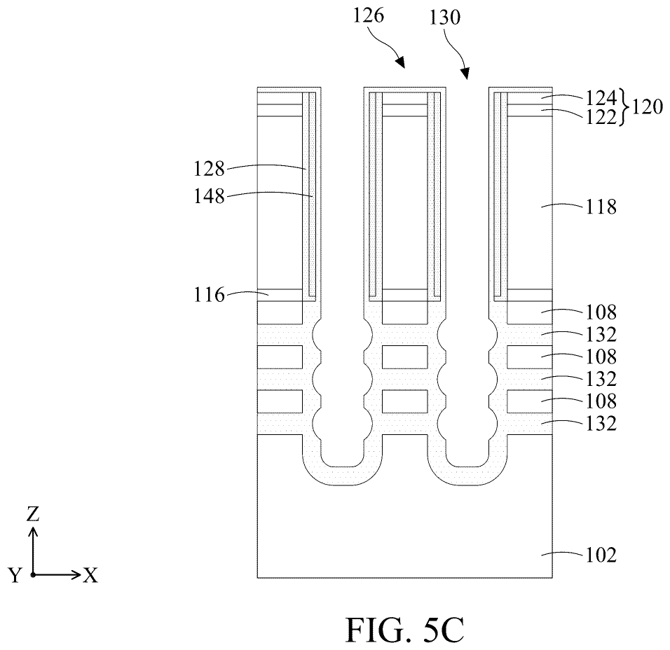

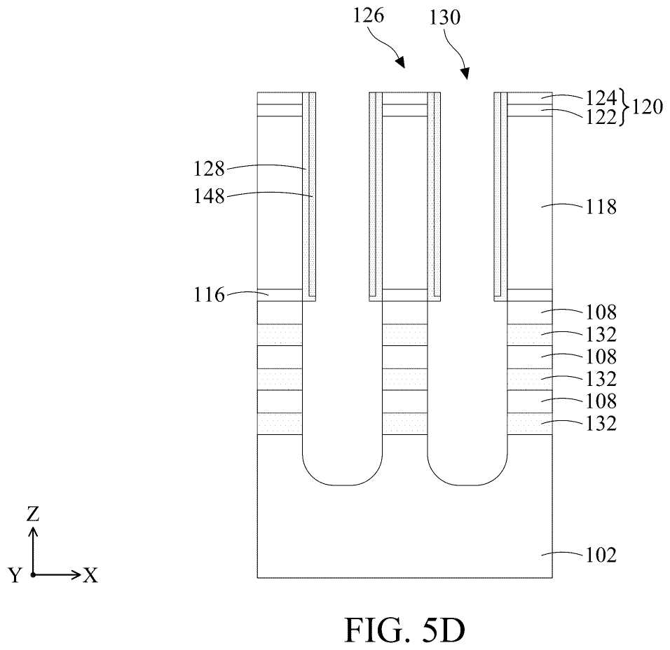

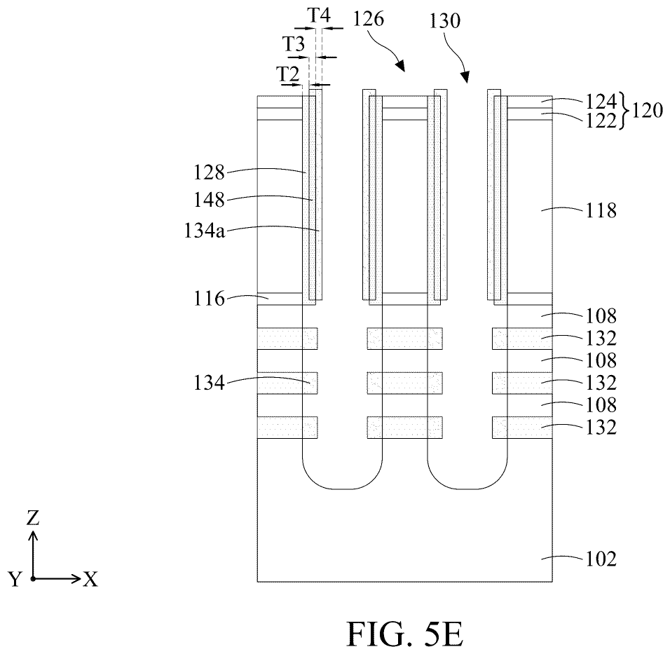

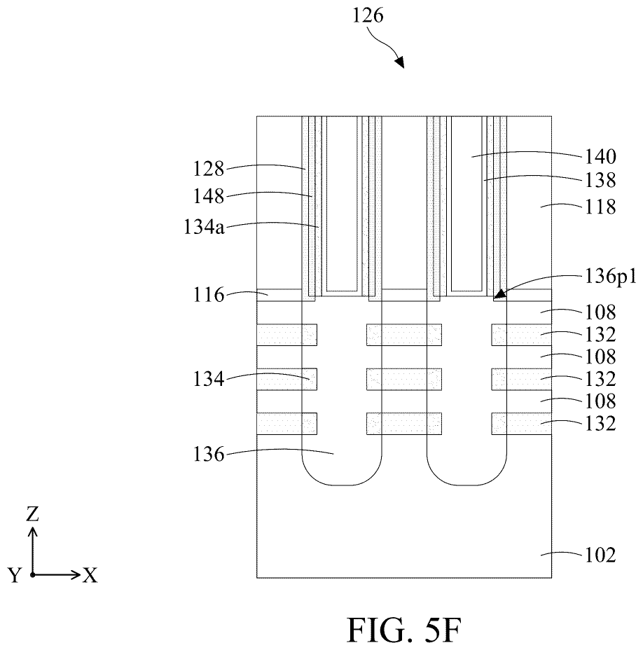

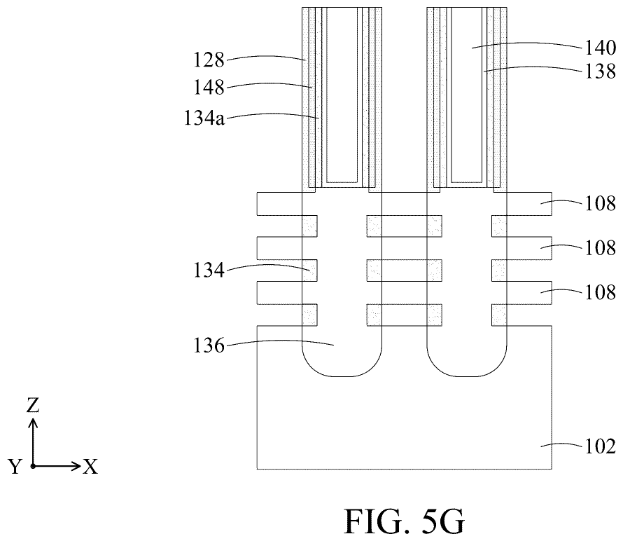

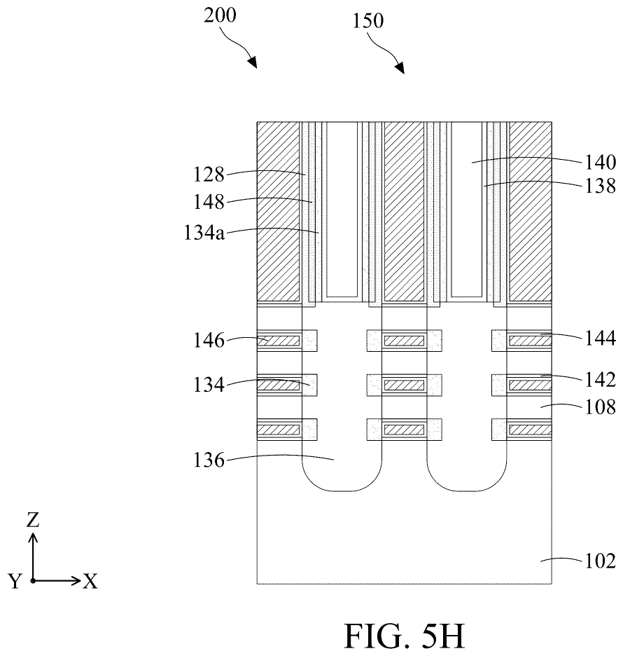

FIGS. 5A to 5H are cross-sectional views of various stages of manufacturing a semiconductor structure 200 in accordance with some embodiments of the present disclosure. FIG. 5A is subsequent to the step of the process that is illustrated in FIG. 2B, and the same or similar reference numbers are used to depict the same or similar components as those of the semiconductor structure 200, so for the sake of simplicity, those components will not be discussed in detail again. In the following embodiments, nitride spacers 134 are selectively formed on an oxide spacer layer 148 over the spacer layer 128.

As illustrated in FIG. 5A, a spacer layer 128 is conformally formed over the stack 104 and the dummy gate structure 118, and a spacer layer 148 is conformally formed over the spacer layer 128, in accordance with some embodiments. The spacer layer 148 may be made of oxide, including silicon oxide, silicon oxynitride, silicon carbonitride, silicon oxycarbide, silicon oxycarbonitride, another suitable material, or a combination thereof. Thus, the oxide spacer layer 148 may also be referred to as an oxide spacer layer. The oxide spacer layer 148 may be formed by a deposition process, including a CVD (such as FCVD, PECVD, or LPCVD) process, a spin-on-glass process, another suitable process, or a combination thereof. The material of the oxide spacer layer 148 may be similar to or different from the material of the spacer layer 128.

Then, as illustrated in FIG. 5B, the spacer layer 128 and the oxide spacer layer 148 are etched by an etching process to form a pair of spacer layers 128 on opposite sidewalls of each of the dummy gate structures 126 and a pair of oxide spacer layers 148 on the spacer layers 128, in accordance with some embodiments. The etching process may include a dry etching (e.g., RIE) process, a wet etching process, or a combination thereof. In some embodiments, the sacrificial layers 106 and the channel layers 108 are partially removed in the etching process using the spacer layers 128 and the oxide spacer layers 148 as the mask to form an opening, and then the opening is widen by a trimming process to form a source/drain trench 130. The source/drain trench 130 may extend vertically through the depth of the stack 104 and may partially extend into the substrate 102.

The trimming process may laterally remove the outer portions of the sacrificial layers 106 and the channel layers 108. The trimming process may include a dry etching process or another suitable process. After the trimming process, the bottom surfaces of the spacer layers 128 may be exposed by the source/drain trench 130. In particular, the sidewall of the source/drain trench 130 may be substantially aligned with the sidewall of the dummy gate structure 126.

After the etching process, the spacer layers 128 may have a thickness T2 and the oxide spacer layers 148 may have a thickness T3. The thickness T2 of the spacer layers 128 may be in a range of about 1 nm to about 2 nm. The thickness T3 of the oxide spacer layers 148 may be in a range of about 1 nm to about 2 nm. The thickness T2 of the spacer layers 128 may be substantially equal to or different from the thickness T3 of the oxide spacer layers 148. The thickness T2 of the spacer layers 128 may be less than the thickness T1 of the oxide spacer layers 128 in the semiconductor structure 100 of FIG. 2C. The thickness T3 of the oxide spacer layers 148 may be less than the thickness T1 of the spacer layers 128 in the semiconductor structure 100 of FIG. 2C. The sum of the thickness T2 of the spacer layers 128 and the thickness T3 of the oxide spacer layers 148 may be less than the thickness T1 of the spacer layers 128 in the semiconductor structure 100 of FIG. 2C. Since the total thickness is reduced, it would be easier to performing the trimming process.

In some embodiments, the distance D1 between the stacks 104 (i.e., the width of the source/drain trench 130) is greater than the distance D3 between the oxide spacer layers 148 on adjacent dummy gate structures 126. The distance D1 between the stacks 104 may be substantially equal to the sum of the distance D3 between the oxide spacer layers 148 and the thickness T2 of the spacer layers 128 and the thickness T3 of the oxide spacer layers 148 on adjacent dummy gate structures 126.

Then, as illustrated in FIG. 5C, similar to those discussed with reference to FIG. 2D, the sacrificial layers 106 may be removed to form a plurality of gate openings (not shown) between the channel layers 108 by a selective etching process. Next, a dummy oxide layer 132 may be formed in the gate openings and conformally on the sidewalls of the source/drain trench 130.

Then, as illustrated in FIG. 5D, similar to those discussed with reference to FIG. 2E, the dummy oxide layer 132 may be partially etched to remove the portions of the dummy oxide layer 132 outside the channel layers 108.

Then, as illustrated in FIG. 5E, a plurality of nitride spacers 134 are selectively formed on the sidewalls of the dummy oxide layer 132 through the source/drain trench 130 and on the sidewalls of the oxide spacer layers 148, in accordance with some embodiments. The nitride spacers 134 may have a portion formed on the sidewalls of the dummy oxide layer 132, which may also be referred to as inner spacers or nitride inner spacers. The nitride spacers 134 may have another portion 134a formed on the sidewalls of the oxide spacer layers 148, which may also be referred to as nitride spacer layers 134a.

By selectively forming the inner spacers 134 on the dummy oxide layer 132, multiple etching and deposition for forming the inner spacers can be omitted, thereby simplifying the manufacturing processes. Therefore, the product level speed and standby power variation can be improved.

In addition, the nitride spacer layers 134a may be selectively formed on the oxide spacer layers 148 to achieve the desired thickness of the spacer layers on the dummy gate electrode layer 118, which may be the sum of the thickness T2 of the spacer layers 128, the thickness T3 of the oxide spacer layers 148, and the thickness T4 of the nitride spacer layers 134a. That is, the desired thickness of the spacer layers can be achieved even though the total thickness of the thickness of the spacer layers are reduced to facilitate the trimming process of the source/drain trench.

The sum of the thickness T2 of the spacer layers 128, the thickness T3 of the oxide spacer layers 148, and the thickness T4 of the nitride spacer layers 134a may be substantially equal to the thickness T1 of the spacer layers 128 in the semiconductor structure 100 of FIG. 2C. The sum of the thickness T2 of the spacer layers 128, the thickness T3 of the oxide spacer layers 148, and the thickness T4 of the nitride spacer layers 134a may be in a range of about 5 nm to about 6 nm.

The thickness T4 of the nitride spacer layers 134a may be greater than or substantially equal to the thickness T2 of the spacer layers 128. The thickness T4 of the nitride spacer layers 134a may be greater than or substantially equal to the thickness T3 of the oxide spacer layers 148. The thickness T4 of the nitride spacer layers 134a may be in a range of about 1 nm to about 2 nm.

The nitride inner spacers 134 may laterally extend (such as laterally protrude) from the sidewalls of the dummy oxide layer 132. The inner sidewalls of the nitride inner spacers 134 may be substantially aligned with the sidewalls of the dummy oxide layer 132 and substantially aligned with the sidewalls of the channel layers 108. The nitride inner spacers 134 may laterally extend (such as laterally protrude) from the sidewall of the spacer layers 128 in a direction that is parallel to the sidewall of the spacer layers 128. The nitride inner spacers 134 may laterally extend (such as laterally protrude) from the sidewall of the oxide spacer layers 148 when viewed from above, or from a direction that is parallel to the sidewall of the oxide spacer layers 148.

The nitride spacer layers 134a may be formed on the top surface and the sidewalls of the oxide spacer layers 148, and may have a length substantially equal to the length of the oxide spacer layers 148 in a direction that is parallel to the sidewall of the oxide spacer layers 148. The length of the spacer layers 128 may be greater than the length of the nitride spacer layers 134a and may be greater than the length of the oxide spacer layers 148 in a direction that is parallel to the sidewall of the oxide spacer layers 148. The bottom portion of the spacer layers 128 may extend below the bottom portion of the oxide spacer layers 148 and the bottom portion of the nitride spacer layers 134a.

Then, as illustrated in FIG. 5F, similar to those discussed with reference to FIG. 2G, a source/drain structure 136 may be formed in the source/drain trench 130. The outermost sidewall of the source/drain structure 136 may be substantially aligned with the sidewall of the spacer layers 128. The source/drain structure 136 may extend from a sidewall of the nitride inner spacers 134 to another sidewall of the nitride inner spacers 134 and may encapsulate the nitride inner spacers 134. The outermost sidewall of the source/drain structure 136 may be substantially aligned with the interface between the nitride inner spacers 134 and the dummy oxide layer 132.

Since the bottom surface of the spacer layers 128, the bottom surface of the oxide spacer layers 148 and the bottom surface of the nitride spacer layers 134a are not aligned with each other, the source/drain structure 136 may have an uneven top surface. In particular, the top portion of the source/drain structure 136 may have a protrusion 136p1 in the center. The protrusion 136p1 may be surrounded by the bottom portion of the spacer layers 128 and below the bottom surface of the oxide spacer layers 148 and the bottom surface of the nitride spacer layers 134a. The source/drain structure 136 may have a stepped sidewall on the edge, which may include the top surfaces of the source/drain structure 136 at different heights.

Next, an etch stop layer 138 may formed over the source/drain structure 136, and then an inter-layer dielectric (ILD) structure 140 may be formed over the etch stop layer 138, similar to those discussed with reference to FIG. 2G. Then, a planarization process may be performed on the ILD structure 140 until the top surface of the dummy gate structure 118 is exposed. After the planarization process, the top surface of the dummy gate structure 118 may be substantially level with the top surfaces of the spacer layers 128, the oxide spacer layers 148, the nitride spacer layers 134a, the etch stop layer 138, and the ILD structure 140.

Next, as illustrated in FIG. 5G, similar to those discussed with reference to FIG. 2H, the dummy gate structure 118 and the dummy oxide layer 132 may be removed. Then, as illustrated in FIG. 5H, similar to those discussed with reference to FIG. 2I, gate structures 150 may be formed surrounding the channel layers 108. Each of the gate structures 150 may include an interfacial layer 142, a high-k dielectric layer 144, and a gate electrode layer 146. The channel layers 108 may be surrounded and in direct contact with the interfacial layer 142. The high-k dielectric layer 144 may be surrounded by the interfacial layer 142. The high-k dielectric layer 144 may be surrounded by the gate electrode layer 146. The gate electrode layer 146 may include one or more work function layers and a metal fill layer. Then, a planarization process may be performed until the ILD structure 140 is exposed. The semiconductor structure 200 may be formed.

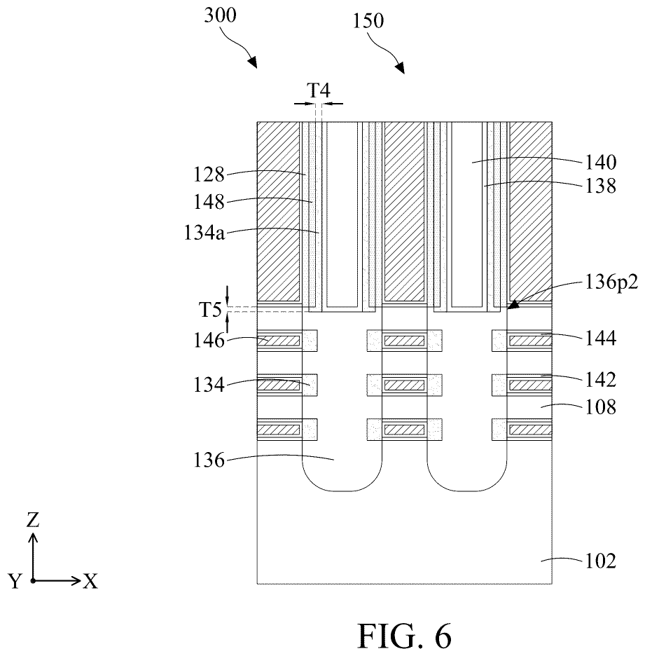

FIG. 6 illustrates a cross-sectional view of a semiconductor structure 300 in accordance with some embodiments of the present disclosure. It should be noted that the semiconductor structure 300 may include the same or similar components as those of the semiconductor structure 200, which is illustrated in FIG. 5H, and for the sake of simplicity, those components will not be discussed in detail again. In the following embodiments, the nitride inner spacers 134 may be selectively formed on the bottom surface of the oxide spacer layers 148.

As illustrated in FIG. 6, the length of the spacer layers 128 may be substantially equal to the length of the oxide spacer layers 148 in a direction that is parallel to the sidewall of the oxide spacer layers 148. This may be formed by, for example, etching the spacer layers 128 during trimming the source/drain trench 130 (illustrated in FIG. 2C). The bottom surface of the oxide spacer layers 148 may be substantially aligned with the bottom surface of the spacer layers 128 and may be exposed. As a result, the nitride spacer layers 134a may be selectively formed on the bottom surface of the oxide spacer layers 148.

As illustrated in FIG. 6, the thickness T4 of the nitride spacer layers 134a on the sidewalls of the oxide spacer layers 148 may be greater than or substantially equal to the thickness T5 of the nitride spacer layers 134a below the bottom surface of the oxide spacer layers 148. The nitride spacer layers 134a may have a length greater than the length of the oxide spacer layers 148 and greater than the length of the spacer layers 128 in a direction that is parallel to the sidewall of the oxide spacer layers 148. The bottom portion of the nitride spacer layers 134a may extend below the bottom portion of the oxide spacer layers 148 and the bottom portion of the spacer layers 128.

The bottom surface of the oxide spacer layers 148 may be separated from the source/drain structure 136 by the nitride spacer layers 134a. Since the bottom surface of the spacer layers 128, the bottom surface of the oxide spacer layers 148 and the bottom surface of the nitride spacer layers 134a are not aligned with each other, the source/drain structure 136 may have an uneven top surface. In particular, the top portion of the source/drain structure 136 may have a protrusion 136p2 on the edge. The protrusions 136p2 may extend between the bottom portion of the nitride spacer layers 134a and the top portion of the channel layers 108. The source/drain structure 136 may have a stepped sidewall on the edge, which may include the top surfaces of the source/drain structure 136 at different heights.

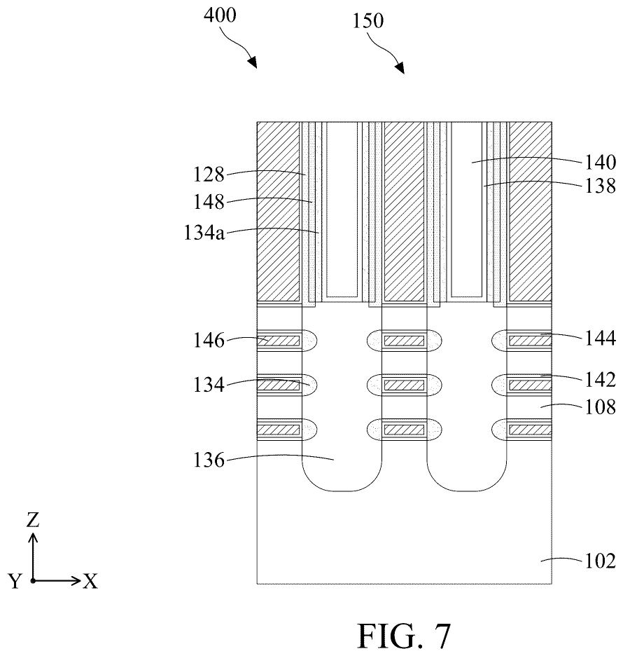

FIG. 7 illustrates a cross-sectional view of a semiconductor structure 400 in accordance with some embodiments of the present disclosure. It should be noted that the semiconductor structure 400 may include the same or similar components as those of the semiconductor structure 200, which is illustrated in FIG. 5H, and for the sake of simplicity, those components will not be discussed in detail again. In the following embodiments, the nitride inner spacers 134 have curved sidewalls.

As illustrated in FIG. 7, the sidewalls of the nitride inner spacers 134 adjoining the source/drain structure 136 may have a curved shape due to the process before the formation of the source/drain structure 136, including the etching process, the forming process, or other processes. In particular, the interface between the nitride inner spacers 134 and the source/drain structure 136 may have a curved shape. The thickness of the nitride inner spacers 134 may increase from the edge to the center of the nitride inner spacers 134. The curved shape is for illustrative purposes only, and the sidewalls of the nitride inner spacers 134 may have another shape.

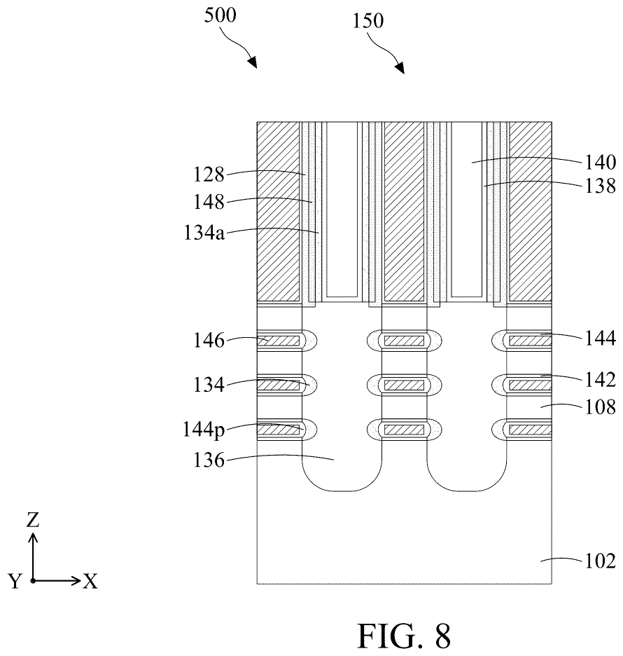

FIG. 8 illustrates a cross-sectional view of a semiconductor structure 500 in accordance with some embodiments of the present disclosure. It should be noted that the semiconductor structure 500 may include the same or similar components as those of the semiconductor structure 400, which is illustrated in FIG. 7, and for the sake of simplicity, those components will not be discussed in detail again. In the following embodiments, the nitride inner spacers 134 have a curved sidewall adjoining the gate structure 150.

As illustrated in FIG. 8, the sidewalls of the nitride inner spacers 134 adjoining the gate structure 150 may have a curved shape due to the process of removing the dummy oxide layer 132 between the channel layers 108 or other processes. The sidewalls of the nitride inner spacers 134 adjoining the source/drain structure 136 may have a curved shape due to the process before the formation of the source/drain structure 136, including the etching process, the forming process, or other processes.

The interface between the nitride inner spacers 134 and the gate structures 150 (such as the high-k dielectric layer 144) may have a curved shape. For example, the high-k dielectric layer 144 may have a protrusion 144p extending into and surrounded by the nitride inner spacers 134. In particular, the thickness of the protrusion 144p may increase from the edge to the center of the high-k dielectric layer 144. The thickness of the nitride inner spacers 134 may increase from the edge to the center of the nitride inner spacers 134.

The curved shape is for illustrative purposes only, and the opposite sidewalls of the nitride inner spacers 134 may have another shape. In addition, the opposite sidewalls of the nitride inner spacers 134 may have different shapes. For example, in some other embodiments, the sidewalls of the nitride inner spacers 134 adjoining the source/drain structure 136 may be straight, and only the sidewalls of the nitride inner spacers 134 adjoining the gate structure 150 have a curved shape.

As described previously, the nitride spacers 134 may be selectively deposited on the surfaces of an oxide, i.e., the surfaces of the dummy oxide layer 132. Therefore, multiple etching and deposition for forming inner spacers can be omitted to simplify the manufacturing processes. In some embodiments as illustrated in FIG. 5H, the nitride spacers 134 may have another portion 134a formed on the sidewalls of the oxide spacer layers 148. Consequently, the desired thickness of the spacer layers can be achieved even though the total thickness of the thickness of the spacer layers are reduced to facilitate the trimming process of the source/drain trench. In some embodiments as illustrated in FIG. 6, the nitride spacer layers 134a may be formed on the bottom surface of the oxide spacer layers 148. In some embodiments as illustrated in FIGS. 7 and 8, the nitride spacers 134 may different shapes due to the subsequent processes.

Embodiments of a semiconductor structure and a method for forming the semiconductor structure are provided. The method may include selectively forming a plurality of nitride spacers on oxide layers, including forming inner spacers and spacer layers. In comparison with forming inner spacers by multiple etching and deposition, manufacturing processes can be simplified. Therefore, the product level speed and standby power variation can be improved.

In some embodiments, a method for forming a semiconductor structure is provided. The method for forming a semiconductor structure includes alternately forming a plurality of channel layers and a plurality of sacrificial layers over a substrate. The method for forming a semiconductor structure also includes forming a source/drain trench through the channel layers and the sacrificial layers. The method for forming a semiconductor structure also includes replacing the sacrificial layers with a plurality of dummy oxide layers. Sidewalls of the dummy oxide layers are substantially aligned with sidewalls of the channel layers. The method for forming a semiconductor structure also includes selectively forming a plurality of inner spacers on the sidewalls of the dummy oxide layers through the source/drain trench. The method for forming a semiconductor structure also includes replacing the dummy oxide layers with a gate structure.

In some embodiments, a method for forming a semiconductor structure is provided. The method for forming a semiconductor structure includes forming a stack over a substrate. The stack includes a plurality of channel layers interleaved by a plurality of sacrificial layers. The method for forming a semiconductor structure also includes forming a dummy gate structure over the stack. The method for forming a semiconductor structure also includes forming a spacer layer on a sidewall of the dummy gate structure. The method for forming a semiconductor structure also includes etching a source/drain trench adjacent to the stack and exposing a bottom surface of the spacer layer. The method for forming a semiconductor structure also includes replacing the sacrificial layers with a plurality of dummy oxide layers. The method for forming a semiconductor structure also includes selectively forming a plurality of nitride spacers on sidewalls of the dummy oxide layers and protruding from a sidewall of the spacer layer when viewed from above. The method for forming a semiconductor structure also includes removing the dummy oxide layers and the dummy gate structure. The method for forming a semiconductor structure also includes forming a gate structure wrapped around the channel layers.

In some embodiments, a semiconductor structure is provided. The semiconductor structure includes nanostructures formed over a substrate. The semiconductor structure also includes a source/drain structure attached to the nanostructures. The semiconductor structure also includes a gate structure wrapped around the nanostructures. The semiconductor structure also includes a spacer layer formed on a sidewall of the gate structure over the nanostructures. The semiconductor structure also includes nitride inner spacers embedded in the source/drain structure. The nitride inner spacers have inner sidewalls adjoining the gate structure and substantially aligned with sidewalls of the nanostructures.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor structure, comprising:
alternately forming a plurality of channel layers and a plurality of sacrificial layers over a substrate;
forming a source/drain trench through the channel layers and the sacrificial layers;
replacing the sacrificial layers with a plurality of dummy oxide layers, wherein sidewalls of the dummy oxide layers are substantially aligned with sidewalls of the channel layers;
selectively forming a plurality of inner spacerson the sidewalls of the dummy oxide layers through the source/drain trench; and
replacing the dummy oxide layers with a gate structure.

2. The method for forming the semiconductor structure as claimed in claim 1, further comprising:
forming a dummy gate structure over the channel layers and the sacrificial layers; and
forming a first spacer layer on a sidewall of the dummy gate structure,
wherein a bottom surface of the first spacer layer is exposed by the source/drain trench.

3. The method for forming the semiconductor structure as claimed in claim 2, further comprising:
forming a second spacer layer on a sidewall of the first spacer layer; and
forming a third spacer layer on a sidewall of the second spacer layer during forming the inner spacers,
wherein the second spacer layer and the third spacer layer are formed of different materials.

4. The method for forming the semiconductor structure as claimed in claim 3, wherein the inner spacers laterally extend from the sidewall of the first spacer layer and the sidewall of the second spacer layer when viewed in a direction parallel to the sidewall of the first spacer layer.

5. The method for forming the semiconductor structure as claimed in claim 2, wherein forming the source/drain trench comprises:
etching an opening using the first spacer layer as a mask;
widening the opening to form the source/drain trench so that a sidewall of the source/drain trench is substantially aligned with a sidewall of the dummy gate structure.

6. The method for forming the semiconductor structure as claimed in claim 1, further comprising:
after replacing the sacrificial layers with the dummy oxide layers, forming a source/drain structure in the source/drain trench,
wherein the inner spacers are embedded in the source/drain structure.

7. The method for forming the semiconductor structure as claimed in claim 6, wherein the source/drain structure has a stepped sidewall at a top portion of the source/drain structure.

8. A method for forming a semiconductor structure, comprising:
forming a stack over a substrate, wherein the stack comprises a plurality of channel layers interleaved by a plurality of sacrificial layers;
forming a dummy gate structure over the stack;
forming a spacer layer on a sidewall of the dummy gate structure;
etching a source/drain trench adjacent to the stack and exposing a bottom surface of the spacer layer;
replacing the sacrificial layers with a plurality of dummy oxide layers;
selectively forming a plurality of nitride spacers on sidewalls of the dummy oxide layers and protruding from a sidewall of the spacer layer when viewed from above;
removing the dummy oxide layers and the dummy gate structure; and
forming a gate structure wrapped around the channel layers.

9. The method for forming the semiconductor structure as claimed in claim 8, wherein the spacer layer comprises a nitride layer and an oxide layer on a nitride layer, and the nitride spacers are selectively formed on sidewalls of the oxide layer when selectively formed on the sidewalls of the dummy oxide layers.

10. The method for forming the semiconductor structure as claimed in claim 9, further comprising selectively forming the nitride spacers on bottom surfaces of the oxide layer.

11. The method for forming the semiconductor structure as claimed in claim 8, wherein the nitride spacers are recessed during removing the dummy oxide layers, and the gate structure has a protrusion extending into the nitride spacers.

12. The method for forming the semiconductor structure as claimed in claim 11, wherein a thickness of the nitride spacers increases from an edge to a center of the nitride spacers.

13. The method for forming the semiconductor structure as claimed in claim 8, further comprising forming a source/drain structure in the source/drain trench and on curved sidewalls of the nitride spacers.

14. A semiconductor structure, comprising:
nanostructures formed over a substrate;
a source/drain structure attached to the nanostructures;
a gate structure wrapped around the nanostructures;
a spacer layer formed on a sidewall of the gate structure over the nanostructures; and
nitride inner spacers embedded in the source/drain structure, wherein the nitride inner spacers have inner sidewalls adjoining the gate structure and substantially aligned with sidewalls of the nanostructures.

15. The semiconductor structure as claimed in claim 14, wherein the inner sidewalls of the nitride inner spacers have curved shapes.

16. The semiconductor structure as claimed in claim 14, further comprising:
an oxide spacer layer formed on the spacer layer; and
a nitride spacer layer formed on the oxide spacer layer,
wherein a bottom surface of the spacer layer is substantially aligned with a bottom surface of the oxide spacer layer and above a bottom surface of the nitride spacer layer.

17. The semiconductor structure as claimed in claim 16, wherein the bottom surface of the nitride spacer layer is substantially aligned with the bottom surface of the oxide spacer layer and above the bottom surface of the spacer layer.

18. The semiconductor structure as claimed in claim 17, wherein the source/drain structure has a first top surface in contact with the bottom surface of the nitride spacer layer and a second top surface in contact with the bottom surface of the spacer layer.

19. The semiconductor structure as claimed in claim 14, wherein the source/drain structure encapsulates a curved sidewall of the nitride inner spacers.

20. The semiconductor structure as claimed in claim 14, wherein the inner sidewalls of the nitride inner spacers are substantially aligned with an outermost sidewall of the source/drain structure.
